(19) United States
(12) Patent Application Publication
(10) Pub. No.: US 2023/0262967 A1
(43) Pub. Date: Aug. 17, 2023

(54) SEMICONDUCTOR MEMORY DEVICE

(71) Applicant: Samsung Electronics Co., Ltd., Suwon-si (KR)

(72) Inventors: Jun Hyeok AHN, Suwon-si (KR); Sung Woo Kim, Hwaseong-si (KR); Myeong-Dong LEE, Seoul (KR); Min Ho CHOI, Suwon-si (KR)

(73) Assignee: Samsung Electronics Co., Ltd., Suwon-si (KR)

(21) Appl. No.: 18/048,561

(22) Filed: Oct. 21, 2022

(30) Foreign Application Priority Data
Feb. 14, 2022 (KR) 10-2022-0018991

(51) Int. Cl. H01L 27/108; G11C 5/06

(52) U.S. Cl. CPC H01L 27/10897; G11C 5/063; H01L 27/10814

(57) ABSTRACT

A semiconductor memory device may include a substrate including a cell region and a peripheral region along a periphery of the cell region; a cell region isolation layer along the periphery of the cell region in the substrate and defining the cell region; a cell conductive line on the cell region and including a sidewall on the cell region isolation layer; a peripheral gate conductive layer on the peripheral region and including a sidewall on the cell region isolation layer; and an isolation insulating layer in contact with the sidewall of the cell conductive line and the sidewall of the peripheral gate conductive layer on the cell region isolation layer.

### CROSS-REFERENCE TO RELATED APPLICATION

This application claims priority from Korean Patent Application No. 10-2022-0018991, filed on Feb. 14, 2022 in the Korean Intellectual Property Office, and all the benefits accruing therefrom under 35 U.S.C. 119, the entire contents of which are herein incorporated by reference.

### BACKGROUND

### 1. Technical Field

The present disclosure relates to a semiconductor memory device.

### 2. Description of the Related Art

As semiconductor elements are increasingly highly integrated, individual circuit patterns are becoming more miniaturized in order to implement more semiconductor elements on the same area. That is, as the degree of integration of the semiconductor element increases, a design rule for the components of the semiconductor element is decreasing.

In a highly scaled semiconductor element, a process of forming a plurality of wiring lines and a plurality of buried contacts BC interposed therebetween may become increasingly complex and difficult.

### SUMMARY

Aspects of the present disclosure provide a semiconductor memory device capable of having improved product reliability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an embodiment of inventive concepts, a semiconductor memory device may include a substrate including a cell region and a peripheral region along a periphery of the cell region; a cell region isolation layer in the substrate, the cell region isolation layer along the periphery of the cell region and defining the cell region of the substrate; a cell conductive line on the cell region, the cell conductive line including a sidewall on the cell region isolation layer; a peripheral gate conductive layer on the peripheral region, the peripheral gate conductive layer including a sidewall on the cell region isolation layer; and an isolation insulating layer in contact with the sidewall of the cell conductive line and the sidewall of the peripheral gate conductive layer on the cell region isolation layer.

According to an embodiment of inventive concepts, a semiconductor memory device may include a substrate including a cell region and a peripheral region along a periphery of the cell region; a cell conductive line on the cell region; a peripheral gate conductive layer on the peripheral region, the peripheral gate conductive layer including a first sidewall opposite the cell conductive line in a first direction and a second sidewall opposite the first sidewall in the first direction; a peripheral spacer that is not on the first sidewall and is disposed on the second sidewall; and an isolation insulating layer between the cell conductive line and the first sidewall.

According to an embodiment of inventive concepts, a semiconductor memory device may include a substrate including a cell region and a peripheral region defined around the cell region; a cell region isolation layer defining the cell region in the substrate; a bit line structure on the substrate in the cell region, the bit line structure including a cell conductive line extending in a first direction and a cell line capping layer on the cell conductive line; a cell gate electrode in the substrate in the cell region, the cell gate electrode extending in a second direction to intersect the cell conductive line, the second direction intersecting the first direction; a peripheral gate structure on the substrate in the peripheral region, the peripheral gate structure including a peripheral gate conductive layer and a peripheral capping layer on the peripheral gate conductive layer; an isolation insulating layer isolating the bit line structure and the peripheral gate structure from each other, the isolation insulating layer on the cell region isolation layer between the bit line structure and the peripheral gate structure, and the isolation insulating layer being a single layer; a bit line spacer on sidewalls of the bit line structure facing the second direction, and the bit line spacer not on sidewalls of the bit line structure facing the first direction; and a peripheral spacer on a sidewall of the peripheral gate structure facing the second direction and a sidewall of the peripheral gate structure facing the first direction in which the isolation insulating layer is not disposed. The peripheral spacer may not be on a sidewall of the peripheral gate structure facing the first direction in which the isolation insulating layer is disposed.

### BRIEF DESCRIPTION OF THE DRAWINGS

The above and other aspects and features of the present disclosure will become more apparent by describing in detail example embodiments thereof with reference to the attached drawings, in which:

FIG. 1 is a schematic layout view of a semiconductor memory device according to some example embodiments;

FIG. 2 is a schematic layout of a region R1 of FIG. 1;

FIG. 3 is a schematic layout of a region R2 of FIG. 1;

FIG. 4 is an example cross-sectional view taken along line A-A′ of FIG. 3;

FIG. 5 is an example cross-sectional view taken along line B-B′ of FIG. 3;

FIG. 6 is an example cross-sectional view taken along line C-C′ of FIG. 3;

FIGS. 7 to 10 are views for describing a semiconductor memory device according to some example embodiments;

FIGS. 11 to 18 are intermediate operation views for describing a method for manufacturing a semiconductor memory device according to some example embodiments;

FIGS. 19 to 26 are intermediate operation views for describing the method for manufacturing a semiconductor memory device according to some example embodiments; and

FIGS. 27 and 28 are views for describing a hard mask pattern of FIG. 14.

### DETAILED DESCRIPTION

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

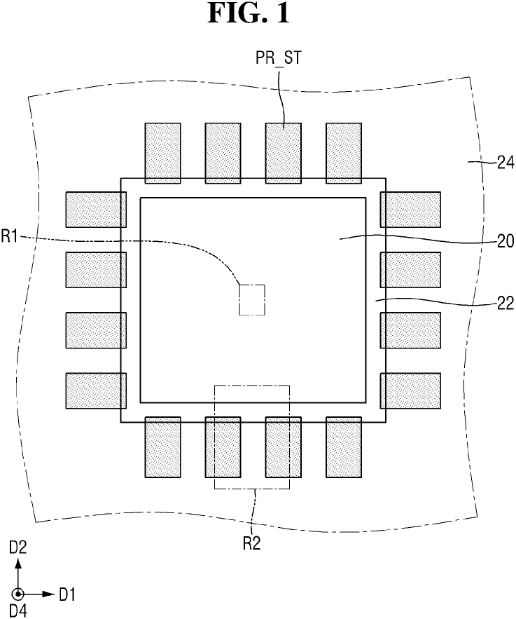

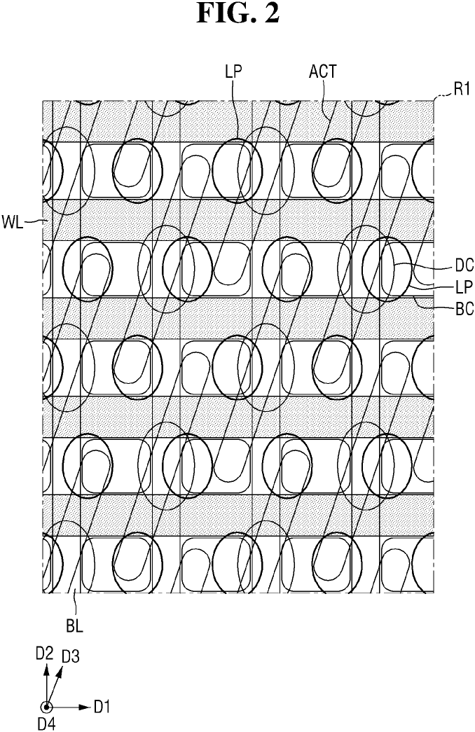

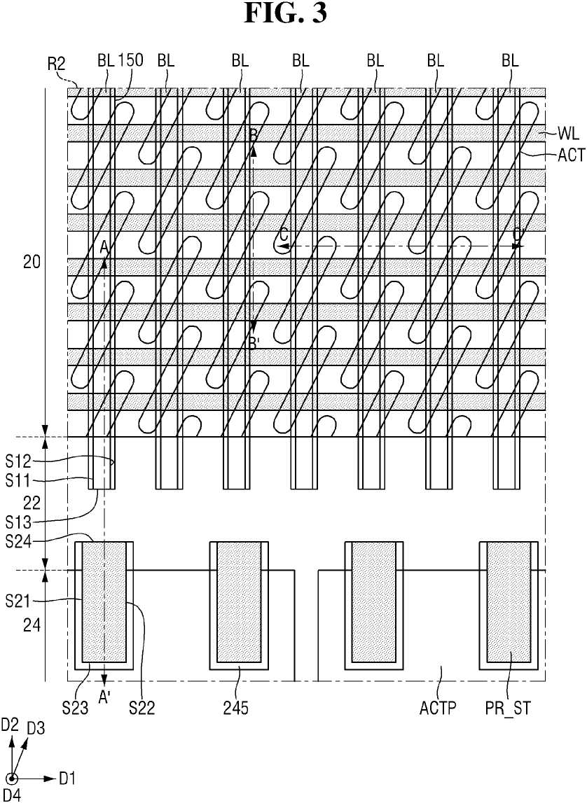

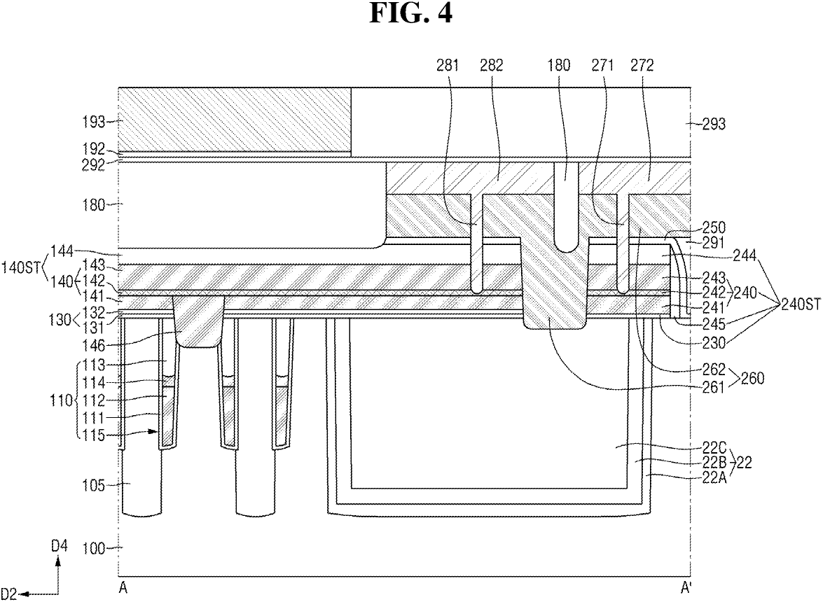

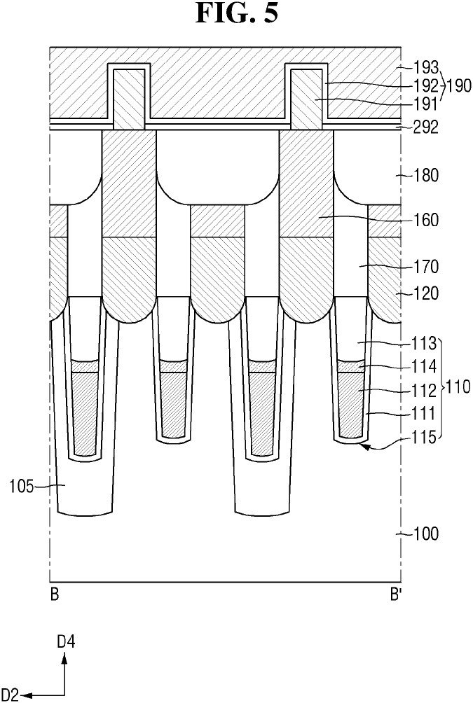

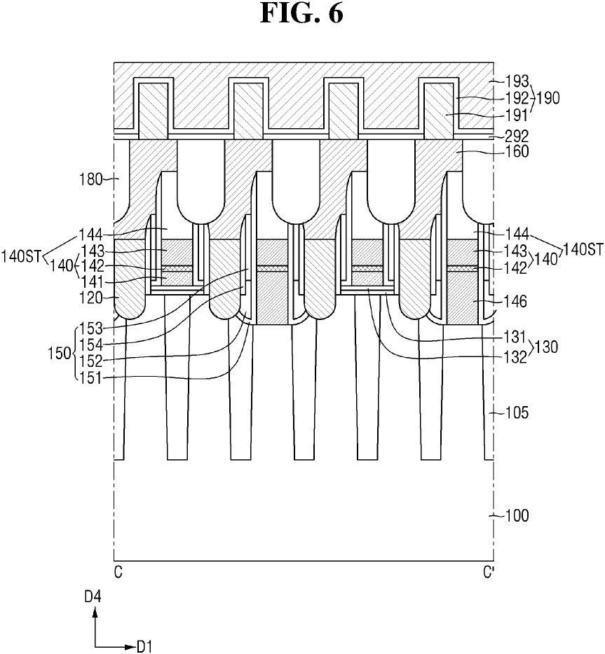

FIG. 1 is a schematic layout view of a semiconductor memory device according to some example embodiments. FIG. 2 is a schematic layout of a region R1 of FIG. 1. FIG. 3 is a schematic layout of a region R2 of FIG. 1. FIG. 4 is an example cross-sectional view taken along line A-A′ of FIG. 3. FIG. 5 is an example cross-sectional view taken along line B-B′ of FIG. 3. FIG. 6 is an example cross-sectional view taken along line C-C′ of FIG. 3.

In the drawings of a semiconductor memory device according to some example embodiments, a dynamic random access memory (DRAM) is illustrated, but the present disclosure is not limited thereto.

Referring to FIGS. 1 to 6, a semiconductor memory device according to some example embodiments may include a cell region 20, a cell region isolation layer 22, and a peripheral region 24.

The cell region isolation layer 22 may be formed along a periphery of the cell region 20. The cell region isolation layer 22 may isolate the cell region 20 and the peripheral region 24. The peripheral region 24 may be defined around the cell region 20.

The cell region 20 may include a plurality of cell active regions ACT. The cell active region ACT may be defined by a cell element isolation layer 105 formed in a substrate 100. As a design rule of the semiconductor memory device is reduced, the cell active region ACT may be disposed in a bar shape of a diagonal line or an oblique line as illustrated. For example, the cell active region ACT may extend in a third direction D3.

A plurality of gate electrodes crossing the cell active region ACT and extending in a first direction D1 may be disposed. The plurality of gate electrodes may extend to be parallel to each other. The plurality of gate electrodes may be, for example, a plurality of word lines WL. The word lines WL may be disposed at equal intervals. A width of the word lines WL or an interval between the word lines WL may be determined according to a design rule.

The word line WL may extend to the cell region isolation layer 22. A portion of the word line WL may overlap the cell region isolation layer 22 in a fourth direction D4.

Each of the cell active regions ACT may be divided into three portions by two word lines WL extending in the first direction D1. The cell active region ACT may include a storage connection region and a bit line connection region. The bit line connection region may be positioned at a central portion of the cell active region ACT, and the storage connection region may be positioned at an end portion of the cell active region ACT.

A plurality of bit lines BL extending in a second direction D2 orthogonal to the word line WL may be disposed on the word line WL. The plurality of bit lines BL may extend to be parallel to each other. The bit lines BL may be disposed at equal intervals. A width of the bit lines BL or an interval between the bit lines BL may be determined according to a design rule.

The bit line BL may extend to the cell region isolation layer 22. A portion of the bit line BL may overlap the cell region isolation layer 22 in the fourth direction D4. An end of the bit line BL in the second direction D2 may be disposed on the cell region isolation layer 22. The fourth direction D4 may be orthogonal to the first direction D1, the second direction D2, and the third direction D3. The fourth direction D4 may be a thickness direction of the substrate 100.

The semiconductor memory device according to some example embodiments may include various contact arrangements formed on the cell active region ACT. Various contact arrangements may include, for example, a direct contact DC, a buried contact BC, and a landing pad LP.

Here, the direct contact DC may refer to a contact that electrically connects the cell active region ACT to the bit line BL. The buried contact BC may refer to a contact that connects the cell active region ACT to a lower electrode 191. Due to an arrangement structure, a contact area between the buried contact BC and the cell active region ACT may be small. Accordingly, a conductive landing pad LP may be introduced to increase the contact area with the lower electrode 191 while increasing the contact area with the cell active region ACT.

The landing pad LP may be disposed between the cell active region ACT and the buried contact BC, and may also be disposed between the buried contact BC and the lower electrode 191. In the semiconductor memory device according to some example embodiments, the landing pad LP may be disposed between the buried contact BC and the lower electrode 191. By increasing the contact area through the introduction of the landing pad LP, contact resistance between the cell active region ACT and the lower electrode 191 may be reduced.

The direct contact DC may be connected to the bit line connection region. The buried contact BC may be connected to the storage connection region. As the buried contact BC is disposed at both end portions of the cell active region ACT, the landing pad LP may be disposed adjacent to both ends of the cell active region ACT to partially overlap the buried contact BC. In other words, the buried contact BC may be formed to overlap the cell active region ACT and the cell element isolation layer 105 between the word lines WL adjacent to each other and between the bit lines BL adjacent to each other.

The word line WL may be formed in a structure buried in the substrate 100. The word line WL may be disposed across the cell active region ACT between the direct contact DC or the buried contact BC. As illustrated, two word lines WL may be disposed to cross one cell active region ACT. As the cell active region ACT extends in the third direction D3, the word line WL may have an angle of less than 90 degrees with the cell active region ACT.

The direct contact DC and the buried contact BC may be symmetrically disposed. Accordingly, the direct contact DC and the buried contact BC may be disposed on one straight line in the first direction D1 and the second direction D2. Meanwhile, unlike the direct contact DC and the buried contact BC, the landing pad LP may be disposed in a zigzag shape in the second direction D2 in which the bit line BL extends. In addition, the landing pad LP may be disposed to overlap the same side portion of each bit line BL in the first direction D1 in which the word line WL extends. For example, each of the landing pads LP of a first line may overlap a left side of a corresponding bit line BL, and each of the landing pads LP of a second line may overlap a right side of a corresponding bit line BL.

The semiconductor memory device according to some example embodiments may include a plurality of cell gate structures 110, a plurality of bit line structures 140ST, a plurality of storage contacts 120, an information storage portion 190, and a peripheral gate structure 240ST.

The substrate 100 may include a cell region 20, a cell region isolation layer 22, and a peripheral region 24. The substrate 100 may be a silicon substrate or a silicon-on-insulator (SOI). Alternatively, the substrate 100 may include silicon germanium, silicon germanium on insulator (SGOI), indium antimonide, lead tellurium compound, indium arsenide, indium phosphide, gallium arsenide, or gallium antimonide, but is not limited thereto.

The plurality of cell gate structures 110, the plurality of bit line structures 140ST, the plurality of storage contacts 120, and the information storage portion 190 may be disposed in the cell region 20. The peripheral gate structure 240ST may be disposed in the peripheral region 24.

The cell element isolation layer 105 may be formed in the substrate 100 of the cell region 20. The cell element isolation layer 105 may have a shallow trench isolation (STI) structure having excellent element isolation characteristics. The cell element isolation layer 105 may define the cell active region ACT in the cell region 20. The cell active region ACT defined by the cell element isolation layer 105 may have a long island shape including a short axis and a long axis as illustrated in FIG. 1. The cell active region ACT may have an oblique shape to have an angle of less than 90 degrees with respect to the word line WL formed in the cell element isolation layer 105. In addition, the cell active region ACT may have an oblique shape to have an angle of less than 90 degrees with respect to the bit line BL formed on the cell element isolation layer 105.

The cell element isolation layer 105 may include, for example, at least one of a silicon oxide layer, a silicon nitride layer, and a silicon oxynitride layer, but is not limited thereto. The cell element isolation layer 105 may be formed as one insulating layer or a plurality of insulating layers depending on a width of the cell element isolation layer 105.

The cell region isolation layer 22 may have an STI structure. The cell region 20 may be defined by the cell region isolation layer 22. The cell region isolation layer 22 may sequentially include a first insulating liner 22A, a second insulating liner 22B, and a third insulating liner 22C. The first insulating liner 22A may include an oxide layer, the second insulating liner 22B may include a nitride layer, and the third insulating liner 22C may include an oxide layer. The cell region isolation layer 22 may be formed as one insulating layer or third or more insulating layers depending on a width of the cell region isolation layer 22.

In the drawing, a top surface of the cell element isolation layer 105, a top surface of the substrate 100, and a top surface of the cell region isolation layer 22 are illustrated as being on the same plane, but this is only for convenience of explanation and the present disclosure is not limited thereto.

The cell gate structure 110 is formed in the substrate 100 and the cell element isolation layer 105. The cell gate structure 110 may be formed across the cell element isolation layer 105 and the cell active region ACT defined by the cell element isolation layer 105. The cell gate structure 110 may include a cell gate trench 115, a cell gate insulating layer 111, a cell gate electrode 112, a cell gate capping pattern 113, and a cell gate capping conductive layer 114 which are formed in the substrate 100 and the cell element isolation layer 105. Here, the cell gate electrode 112 may correspond to the word line WL. Unlike illustrated in the drawing, the cell gate structure 110 may not include the cell gate capping conductive layer 114.

The cell gate insulating layer 111 may extend along a sidewall and a bottom surface of the cell gate trench 115. The cell gate insulating layer 111 may extend along a profile of at least a portion of the cell gate trench 115. The cell gate insulating layer 111 may include, for example, at least one of silicon oxide, silicon nitride, silicon oxynitride, or a high-k material having a dielectric constant higher than that of silicon oxide. The high-k material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and a combination thereof.

The cell gate electrode 112 may be formed on the cell gate insulating layer 111. The cell gate electrode 112 may fill a portion of the cell gate trench 115. The cell gate capping conductive layer 114 may extend along a top surface of the cell gate electrode 112.

The cell gate electrode 112 may include at least one of a metal, a metal alloy, a conductive metal nitride, a conductive metal carbonitride, a conductive metal carbide, a metal silicide, a doped semiconductor material, a conductive metal oxynitride, and a conductive metal oxide. The cell gate electrode 112 may include, for example, at least one of TiN, TaC, TaN, TiSiN, TaSiN, TaTiN, TiAlN, TaAlN, WN, Ru, TiAl, TiAlC-N, TiAlC, TiC, TaCN, W, Al, Cu, Co, Ti, Ta, Ni, Pt, Ni-Pt, Nb, NbN, NbC, Mo, MoN, MoC, WC, Rh, Pd, Ir, Ag, Au, Zn, V, RuTiN, TiSi, TaSi, NiSi, CoSi, IrOx, RuOx, and combinations thereof, but is not limited thereto. The cell gate capping conductive layer 114 may include, for example, polysilicon or polysilicon germanium, but is not limited thereto.

The cell gate capping pattern 113 may be disposed on the cell gate electrode 112 and the cell gate capping conductive layer 114. The cell gate capping pattern 113 may fill the cell gate trench 115 remaining after the cell gate electrode 112 and the cell gate capping conductive layer 114 are formed. The cell gate insulating layer 111 is illustrated as extending along sidewalls of the cell gate capping pattern 113, but is not limited thereto. The cell gate capping pattern 113 may include, for example, at least one of silicon nitride (SiN), silicon oxynitride (SiON), silicon oxide (SiO₂), silicon carbonitride (SiCN), silicon oxycarbonitride (SiOCN), and combinations thereof.

Although not illustrated, an impurity doped region may be formed on at least one side of the cell gate structure 110. The impurity doped region may be a source/drain region of a transistor. The impurity doped region may be formed in the storage connection region and the bit line connection region.

The bit line structure 140ST may include a cell conductive line 140 and a cell line capping layer 144. The cell conductive line 140 may be formed on the substrate 100 and the cell element isolation layer 105 in which the cell gate structure 110 is formed. The cell conductive line 140 may intersect the cell element isolation layer 105 and the cell active region ACT defined by the cell element isolation layer 105. The cell conductive line 140 may be formed to intersect the cell gate structure 110. Here, the cell conductive line 140 may correspond to the bit line BL.

The cell conductive line 140 may be multiple layers. The cell conductive line 140 may include, for example, a first cell conductive layer 141, a second cell conductive layer 142, and a third cell conductive layer 143. The first to third cell conductive layers 141, 142, and 143 may be sequentially stacked on the substrate 100 and the cell element isolation layer 105. The cell conductive line 140 is illustrated as a triple layer, but is not limited thereto.

Each of the first to third cell conductive layers 141, 142, and 143 may include, for example, at least one of a semiconductor material doped with impurities, a conductive silicide compound, a conductive metal nitride, a metal, and a metal alloy. For example, the first cell conductive layer 141 may include a doped semiconductor material, the second cell conductive layer 142 may include at least one of a conductive silicide compound and a conductive metal nitride, and the third cell conductive layer 143 may include at least one of a metal and a metal alloy, but the present disclosure is not limited thereto.

The bit line contact 146 may be formed between the cell conductive line 140 and the substrate 100. That is, the cell conductive line 140 may be formed on the bit line contact 146. For example, the bit line contact 146 may be formed at a point where the cell conductive line 140 intersects a central portion of the cell active region ACT having a long island shape. The bit line contact 146 may be formed between the bit line connection region and the cell conductive line 140.

The bit line contact 146 may electrically connect the cell conductive line 140 and the substrate 100. Here, the bit line contact 146 may correspond to the direct contact DC. The bit line contact 146 may include, for example, at least one of a semiconductor material doped with impurities, a conductive silicide compound, a conductive metal nitride, and a metal.

In FIG. 4, in a region overlapping the top surface of the bit line contact 146, the cell conductive line 140 may include the second cell conductive layer 142 and the third cell conductive layer 143. In a region that does not overlap the top surface of the bit line contact 146, the cell conductive line 140 may include the first to third cell conductive layers 141, 142, and 143.

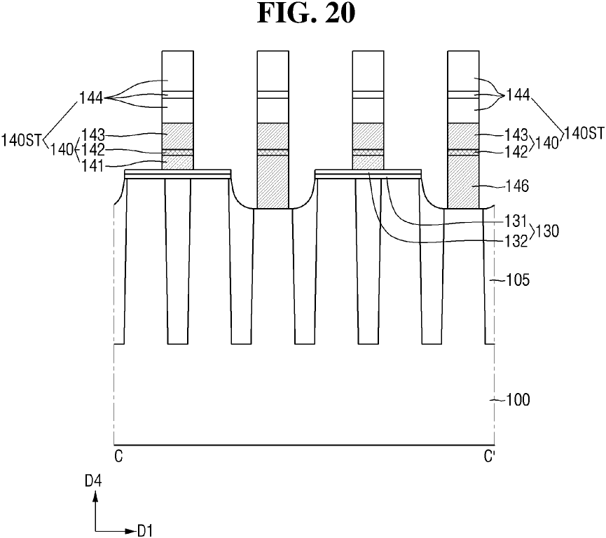

The cell line capping layer 144 may be disposed on the cell conductive line 140. The cell line capping layer 144 may extend in the second direction D2 along the top surface of the cell conductive line 140. In this case, the cell line capping layer 144 may include, for example, at least one of a silicon nitride layer, silicon oxynitride, silicon carbonitride, and silicon oxycarbonitride. In the semiconductor memory device according to some example embodiments, the cell line capping layer 144 may include, for example, a silicon nitride layer. The cell line capping layer 144 is illustrated as a single layer, but is not limited thereto. That is, as illustrated in FIG. 20, the cell line capping layer 144 may be multiple layers. However, when each layer constituting the multiple layers is made of the same material, the cell line capping layer 144 may be viewed as a single layer.

The cell insulating layer 130 may be formed on the substrate 100 and the cell element isolation layer 105. More specifically, the cell insulating layer 130 may be disposed on the substrate 100 and the cell element isolation layer 105 on which the bit line contact 146 is not formed. The cell insulating layer 130 may be disposed between the substrate 100 and the cell conductive line 140 and between the cell element isolation layer 105 and the cell conductive line 140.

The cell insulating layer 130 may be a single layer, but as illustrated, the cell insulating layer 130 may be multiple layers including a first cell insulating layer 131 and a second cell insulating layer 132. For example, the first cell insulating layer 131 may include a silicon oxide layer, and the second cell insulating layer 132 may include a silicon nitride layer, but the present disclosure is not limited thereto.

In the portion of the cell conductive line 140 where the bit line contact 146 is formed, a cell line spacer 150 may be formed on the substrate 100 and the cell element isolation layer 105. The cell line spacer 150 may be disposed on sidewalls of the cell conductive line 140, the cell line capping layer 144, and the bit line contact 146.

In the remaining portion of the cell conductive line 140 where the bit line contact 146 is not formed, the cell line spacer 150 may be disposed on the cell insulating layer 130. The cell line spacer 150 may be disposed on the sidewalls of the cell conductive line 140 and the cell line capping layer 144.

The cell line spacer 150 may be a single layer, but as illustrated, the cell line spacer 150 may be multiple layers including first to fourth cell line spacers 151, 152, 153, and 154. For example, the first to fourth cell line spacers 151, 152, 153, and 154 may include, for example, one of a silicon oxide layer, a silicon nitride layer, a silicon oxynitride layer (SiON), a silicon oxycarbonitride layer (SiOCN), air, and a combination thereof, but are not limited thereto.

For example, the second cell line spacer 152 may not be disposed on the cell insulating layer 130, but may be disposed on the sidewall of the bit line contact 146. On the top surface of the cell gate structure 110, the fourth cell line spacer 154 may extend along the sidewall of the cell conductive line 140 adjacent in the first direction D1 and the top surface of the cell gate capping pattern 113.

The cell conductive line 140 may extend to be long in the second direction D2. The cell conductive line 140 may include a first sidewall S11 and a second sidewall S12 which are short sidewalls opposite to each other in the first direction D1, and a third sidewall S13 and a fourth sidewall which are long sidewalls opposite to each other in the second direction D2. Although not illustrated in the drawing, the cell conductive line 140 further includes a fourth sidewall opposite to the third sidewall S13 in the second direction D2. The third sidewall S13 and the fourth sidewall may be defined on the cell region isolation layer 22.

The cell line spacer 150 may be disposed on at least some of the sidewalls S11, S12, and S13 of the cell conductive line 140. The cell line spacer 150 is disposed on the first sidewall S11 and the second sidewall S12 of the cell conductive line 140, but may not be disposed on the third sidewall S13 and the fourth sidewall of the cell conductive line 140. The third sidewall S13 and the fourth sidewall of the cell conductive line 140 may be exposed by the cell line spacer 150.

A fence pattern 170 may be disposed on the substrate 100 and the cell element isolation layer 105. The fence pattern 170 may be formed to overlap the cell gate structure 110 formed in the substrate 100 and the cell element isolation layer 105. The fence pattern 170 may be disposed between the bit line structures 140ST extending in the second direction D2. The fence pattern 170 may include, for example, at least one of silicon oxide, silicon nitride, silicon oxynitride, and a combination thereof.

The storage contact 120 may be disposed between the cell conductive lines 140 adjacent in the first direction D1. The storage contact 120 may be disposed between the fence patterns 170 adjacent in the second direction D2. The storage contact 120 may overlap the substrate 100 and the cell element isolation layer 105 between the cell conductive lines 140 adjacent to each other. The storage contact 120 may be connected to the storage connection region of the cell active region ACT. Here, the storage contact 120 may correspond to the buried contact BC.

The storage contact 120 may include, for example, at least one of a semiconductor material doped with impurities, a conductive silicide compound, a conductive metal nitride, and a metal.

A storage pad 160 may be formed on the storage contact 120. The storage pad 160 may be electrically connected to the storage contact 120. Here, the storage pad 160 may correspond to the landing pad LP.

The storage pad 160 may overlap a portion of the top surface of the bit line structure 140ST. The storage pad 160 may include, for example, at least one of a semiconductor material doped with impurities, a conductive silicide compound, a conductive metal nitride, a conductive metal carbide, a metal, and a metal alloy.

A pad isolation insulating layer 180 may be formed on the storage pad 160 and the bit line structure 140ST. For example, the pad isolation insulating layer 180 may be disposed on the cell line capping layer 144. The pad isolation insulating layer 180 may define a region of the storage pad 160 forming a plurality of isolated regions. In addition, the pad isolation insulating layer 180 may not cover the top surface of the storage pad 160.

The pad isolation insulating layer 180 may include an insulating material and may electrically isolate the plurality of storage pads 160 from each other. For example, the pad isolation insulating layer 180 may include, for example, at least one of a silicon oxide layer, a silicon nitride layer, a silicon oxynitride layer, a silicon oxycarbonitride layer, and a silicon carbonitride layer.

The information storage portion 190 may be disposed on the storage pad 160. The information storage portion 190 may be electrically connected to the storage pad 160. A portion of the information storage portion 190 may be disposed in an upper etching stop layer 292. The information storage portion 190 may include, for example, a capacitor, but is not limited thereto. The information storage portion 190 includes a lower electrode 191, a capacitor dielectric layer 192, and an upper electrode 193.

The lower electrode 191 may be disposed on the storage pad 160. The lower electrode 191 is illustrated as having a pillar shape, but is not limited thereto. The lower electrode 191 may also have a cylindrical shape. The capacitor dielectric layer 192 is formed on the lower electrode 191. The capacitor dielectric layer 192 may be formed along a profile of the lower electrode 191. The upper electrode 193 is formed on the capacitor dielectric layer 192. The upper electrode 193 may surround an outer sidewall of the lower electrode 191.

For example, the capacitor dielectric layer 192 may be disposed at a portion vertically overlapping the upper electrode 193. As another example, unlike illustrated, the capacitor dielectric layer 192 may include a first portion vertically overlapping the upper electrode 193 and a second portion not vertically overlapping the upper electrode 193. That is, the second portion of the capacitor dielectric layer 192 is a portion that is not covered by the upper electrode 193.

Each of the lower electrode 191 and the upper electrode 193 may include, for example, a doped semiconductor material, a conductive metal nitride (e.g., a titanium nitride, a tantalum nitride, a niobium nitride, a tungsten nitride, or the like), a metal (e.g., ruthenium, iridium, titanium, tantalum, or the like), a conductive metal oxide (e.g., an iridium oxide, a niobium oxide, or the like), and the like, but is not limited thereto.

The capacitor dielectric layer 192 may include, for example, one of silicon oxide, silicon nitride, silicon oxynitride, a high-k material, and combinations thereof, but is not limited thereto. In the semiconductor memory device according to some example embodiments, the capacitor dielectric layer 192 may include a stacked layer structure in which zirconium oxide, aluminum oxide, and zirconium oxide are sequentially stacked. In the semiconductor memory device according to some example embodiments, the capacitor dielectric layer 192 may include a dielectric layer including hafnium (Hf). In the semiconductor memory device according to some example embodiments, the capacitor dielectric layer 192 may have a stacked layer structure of a ferroelectric material layer and a paraelectric material layer.

The peripheral region 24 may include a plurality of peripheral active regions ACTP. The peripheral active region ACTP may be defined by a peripheral device isolation layer.

The peripheral gate structure 240ST may include a peripheral gate insulating layer 230, a peripheral gate conductive layer 240, and a peripheral capping layer 244 sequentially stacked on the substrate 100. The peripheral gate structure 240ST may include a peripheral spacer 245 disposed on a sidewall of the peripheral gate conductive layer 240 and a sidewall of the peripheral capping layer 244.

The peripheral gate conductive layer 240 may include first to third peripheral conductive layers 241, 242, and 243 sequentially stacked on the peripheral gate insulating layer 230. For example, an additional conductive layer may not be disposed between the peripheral gate conductive layer 240 and the peripheral gate insulating layer 230. As another example, unlike illustrated, an additional conductive layer such as a work function conductive layer may be disposed between the peripheral gate conductive layer 240 and the peripheral gate insulating layer 230. Here, the peripheral gate conductive layer 240 may correspond to a peripheral gate PR_ST.

The peripheral gates PR_ST disposed on opposite sidewalls of the cell region 20 in the second direction D2 may constitute a sub-word line driver block, and the peripheral gates PR_ST disposed on opposite sidewalls of the cell region 20 in the first direction D1 may constitute a sense amplifier block. The sub-word line driver block may be arranged in the first direction D1 in which the word line WL extends, and the sense amplifier block may be arranged in the second direction D2 in which the bit line BL extends. In addition to this, peripheral circuits such as a power driver, a ground driver, an inverter chain, and an input/output circuit for driving a bit line sense amplifier may be further formed in the peripheral region 24.

The peripheral gate conductive layer 240 may have the same stacked structure as the cell conductive line 140. The first peripheral conductive layer 241 may include the same material as the first cell conductive layer 141. The second peripheral conductive layer 242 may include the same material as the second cell conductive layer 142. The third peripheral conductive layer 243 may include the same material as the third cell conductive layer 143.

The peripheral gate insulating layer 230 may include, for example, silicon oxide, silicon nitride, silicon oxynitride, or a high-k material having a dielectric constant higher than that of silicon oxide. The peripheral spacer 245 may include, for example, at least one of silicon nitride, silicon oxynitride, silicon oxide, silicon carbonitride, silicon oxycarbonitride, and combinations thereof. The peripheral capping layer 244 may include, for example, at least one of a silicon nitride layer, silicon oxynitride, and silicon oxide.

The peripheral gate conductive layer 240 may include a fifth sidewall S21 and a sixth sidewall S22 opposite to each other in the first direction D1, and a seventh sidewall S23 and an eighth sidewall S24 opposite to each other in the second direction D2. A sidewall of the peripheral gate conductive layer 240 which is closest to the cell conductive line 140 and is opposite to the cell conductive line 140 may be defined on the cell region isolation layer 22. For example, the eighth sidewall S24 of the peripheral gate conductive layer 240 closest to the cell conductive line 140 may be defined on the cell region isolation layer 22. In addition, the third sidewall S13 of the cell conductive line 140 and the eighth sidewall S24 of the peripheral gate conductive layer 240 which are closest to each other may be opposite to each other in the second direction D2.

The peripheral gate conductive layer 240 closest to the cell conductive line 140 may extend to the cell region isolation layer 22. A portion of the peripheral gate conductive layer 240 may overlap the cell region isolation layer 22 in the fourth direction D4. An end of the peripheral gate conductive layer 240 closest to the cell conductive line 140 may be disposed on the cell region isolation layer 22.

The peripheral spacer 245 may be disposed on the sidewalls S21, S22, S23, and S24 of the peripheral gate conductive layer 240 that is not closest to the cell conductive line 140, and may be disposed on at least some of the sidewalls S21, S22, S23, and S24 of the peripheral gate conductive layer 240 closest to the cell conductive line 140. The peripheral gate conductive layer 240 may not be disposed between the cell conductive line 140 and the peripheral gate conductive layer 240 closest to the cell conductive line 140. The peripheral spacer 245 may be disposed on sidewalls of the cell conductive line 140, excluding the sidewalls opposite to the third sidewall S13 and the fourth sidewall thereof. For example, the peripheral spacer 245 is disposed on the fifth to seventh sidewalls S21, S22, and S23 of the peripheral gate conductive layer 240 adjacent to the cell conductive line 140, but may not be disposed on the eighth sidewall S24 thereof. The sidewall of the peripheral gate conductive layer 240 which is closest to the cell conductive line 140 and is opposite to the cell conductive line 140 may be exposed by the peripheral spacer 245.

A lower etching stop layer 250 may be disposed on the substrate 100. The lower etching stop layer 250 may be formed along a profile of the peripheral gate structure 240ST and a profile of the peripheral spacer 245. The lower etching stop layer 250 may extend along a portion of the top surface of the bit line structure 140ST. The lower etching stop layer 250 may extend, for example, along the top surface of the bit line structure 140ST on the cell region isolation layer 22. The lower etching stop layer 250 may include, for example, at least one of a silicon nitride layer, silicon oxynitride, silicon carbonitride, and silicon oxycarbonitride.

A first peripheral interlayer insulating layer 291 may be disposed on the lower etching stop layer 250. The first peripheral interlayer insulating layer 291 may be disposed around the peripheral gate structure 240ST. The first peripheral interlayer insulating layer 291 may not be disposed on a sidewall of the peripheral gate structure 240ST which is closest to the cell conductive line 140 and is opposite to the cell conductive line 140. For example, the first peripheral interlayer insulating layer 291 may not be disposed on the eighth sidewall S24 of the peripheral gate conductive layer 240 opposite to the third sidewall S13 of the cell conductive line 140.

The isolation insulating layer 260 may include a first portion 261 and a second portion 262.

The first portion 261 may be disposed on the cell region isolation layer 22. The first portion 261 may be disposed between the cell conductive line 140 and the peripheral gate conductive layer 240. The first portion 261 may be disposed between an end of the cell conductive line 140 and an end of the peripheral gate conductive layer 240 which is closest to the cell conductive line 140 and is opposite to the end of the cell conductive line 140. The first portion 261 may be in contact with the end of the cell conductive line 140 and the end of the peripheral gate conductive layer 240 which is closest to the cell conductive line 140 and is opposite to the end of the cell conductive line 140. For example, the first portion 261 may be in contact with the third sidewall S13 of the cell conductive line 140 and the eighth sidewall S24 of the peripheral gate conductive layer 240 closest to the cell conductive line 140. Accordingly, the first portion 261 may isolate the cell conductive line 140 and the peripheral gate conductive layer 240 from each other.

In some example embodiments, the first portion 261 of the isolation insulating layer 260 may be spaced apart from a peripheral gate contact plug 271 and a bit line contact plug 281. The first portion 261 may not be in contact with the peripheral gate contact plug 271 and the bit line contact plug 281.

A bottom surface of the first portion 261 may be disposed below a top surface of the substrate 100. Alternatively, the bottom surface of the first portion 261 may be on the same plane as the top surface of the substrate 100.

The second portion 262 may be connected to the first portion 261, and may cover the end of the cell conductive line 140 and the peripheral gate structure 240ST. The second portion 262 may extend along a top surface of the lower etching stop layer 250 and a top surface of the first peripheral interlayer insulating layer 291.

The isolation insulating layer 260 may be a single layer. The isolation insulating layer 260 may include an insulating material to electrically isolate the cell conductive line 140 and the peripheral gate conductive layer 240 closest to the cell conductive line 140 from each other. The isolation insulating layer 260 may include an insulating material other than an oxide layer. For example, the isolation insulating layer 260 may include a silicon nitride layer, a silicon oxynitride layer, a silicon oxycarbonitride layer, and a silicon carbonitride layer.

The peripheral gate contact plug 271 may penetrate through the isolation insulating layer 260, the lower etching stop layer 250, and the peripheral capping layer 244 to be electrically connected to the peripheral gate conductive layer 240. The peripheral gate contact plug 271 may penetrate through the second portion 262 of the isolation insulating layer 260. A bottom surface of the peripheral gate contact plug 271 may be disposed on, for example, the second peripheral conductive layer 242, but is not limited thereto. The bottom surface of the peripheral gate contact plug 271 may be disposed on the first peripheral conductive layer 241 or the third peripheral conductive layer 243. A peripheral connection wiring 272 may be connected to the peripheral gate contact plug 271.

The bit line contact plug 281 may penetrate through the isolation insulating layer 260, the lower etching stop layer 250, and the cell line capping layer 144 to be electrically connected to the cell conductive line 140. The bit line contact plug 281 may penetrate through the second portion 262 of the isolation insulating layer 260. A bottom surface of the bit line contact plug 281 may be disposed on, for example, the second cell conductive layer 142, but is not limited thereto. The bottom surface of the bit line contact plug 281 may be disposed on the first cell conductive layer 141 or the third cell conductive layer 143. The cell connection wiring 282 may be disposed on the isolation insulating layer 260. The cell connection wiring 282 may be connected to the bit line contact plug 281.

The peripheral gate contact plug 271, the peripheral connection wiring 272, the bit line contact plug 281, and the cell connection wiring 282 may include, for example, at least one of a silicon oxide layer, a silicon nitride layer, a silicon oxynitride layer, a silicon oxycarbonitride layer, and a silicon carbonitride layer.

The peripheral connection wiring 272 and the cell connection wiring 282 may be isolated from each other by, for example, the pad isolation insulating layer 180. The peripheral connection wiring 272 and the cell connection wiring 282 may be isolated from each other by, for example, a separate isolation insulating layer other than the pad isolation insulating layer 180.

The upper etching stop layer 292 may be disposed on the pad isolation insulating layer 180 and the storage pad 160. The upper etching stop layer 292 may extend not only to the cell region 20 but also to the peripheral region 24. The upper etching stop layer 292 may be disposed on the peripheral connection wiring 272 and the cell connection wiring 282. The upper etching stop layer 292 may include at least one of a silicon nitride layer, a silicon carbonitride layer, a silicon boron nitride layer (SiBN), a silicon oxynitride layer, and a silicon oxycarbide layer.

A second peripheral interlayer insulating layer 293 may be disposed on the upper etching stop layer 292. The second peripheral interlayer insulating layer 293 may cover a sidewall of the upper electrode 193. The second peripheral interlayer insulating layer 293 may include an insulating material.

When a layer between the cell conductive line 140 and the peripheral gate conductive layer 240 includes silicon oxide, the layer may be etched together in a process of patterning the cell conductive line 140 (a process of patterning the bit line BL) because of having poor resistance to a dry etching process. For example, as illustrated in FIGS. 2 or 3, in a process of etching a pre-cell conductive line to form the cell conductive line 140 extending to be long in the second direction D2, the layer may be etched together. In addition, the layer may be etched together in a process of forming the peripheral gate contact plug 271 and the bit line contact plug 281. Accordingly, the contact plugs 271 and 281 adjacent to each other may be electrically connected to each other, and a reliability of the semiconductor memory device may be deteriorated.

However, in the semiconductor memory device according to some example embodiments, the cell conductive line 140 and the peripheral gate conductive layer 240 are isolated from each other by the isolation insulating layer 260 including the insulating materials except for the oxide layer. Therefore, since the isolation insulating layer 260 has resistance to the dry etching process, the isolation insulating layer 260 may not be etched together in the process of patterning the cell conductive line 140 or the process of forming the peripheral gate contact plug 271 and the bit line contact plug 281. Accordingly, the reliability of the semiconductor memory device may be improved or increased.

In addition, in the semiconductor memory device according to some example embodiments, between the cell conductive line 140 and the peripheral gate conductive layer 240 that are closest to each other, only the isolation insulating layer 260, which is a single layer, is disposed, and the cell line spacer 150 and the peripheral spacer 245 are not disposed. Therefore, compared to the case in which the cell line spacer 150 and the peripheral spacer 245 are disposed between the cell conductive line 140 and the peripheral gate conductive layer 240 that are closest to each other, a distance between the cell conductive line 140 and the peripheral gate conductive layer 240 that are closest to each other may be reduced. Accordingly, a size of the semiconductor memory device may be reduced.

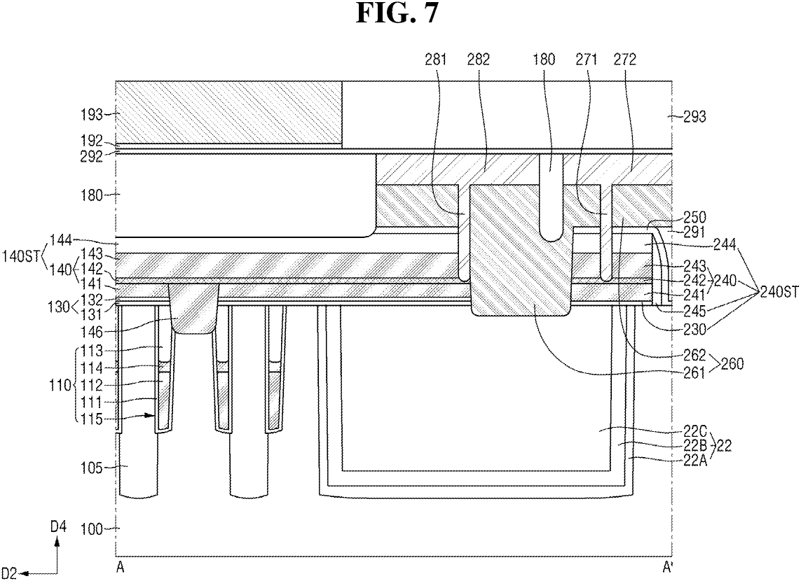

FIGS. 7 to 10 are views for describing a semiconductor memory device according to some example embodiments. For convenience of explanation, points different from those described with reference to FIGS. 1 to 6 will be mainly described. For reference, FIGS. 7 to 10 are cross-sectional views taken along line A-A′ of FIG. 3.

Referring to FIG. 7, in the semiconductor memory device according to some example embodiments, the first portion 261 of the isolation insulating layer 260 may be in contact with any one of the peripheral gate contact plug 271 and the bit line contact plug 281. For example, the first portion 261 of the isolation insulating layer 260 may be in contact with at least a portion of a sidewall of any one of the peripheral gate contact plug 271 and the bit line contact plug 281.

For example, the first portion 261 may be in contact with at least a portion of a sidewall of the bit line contact plug 281.

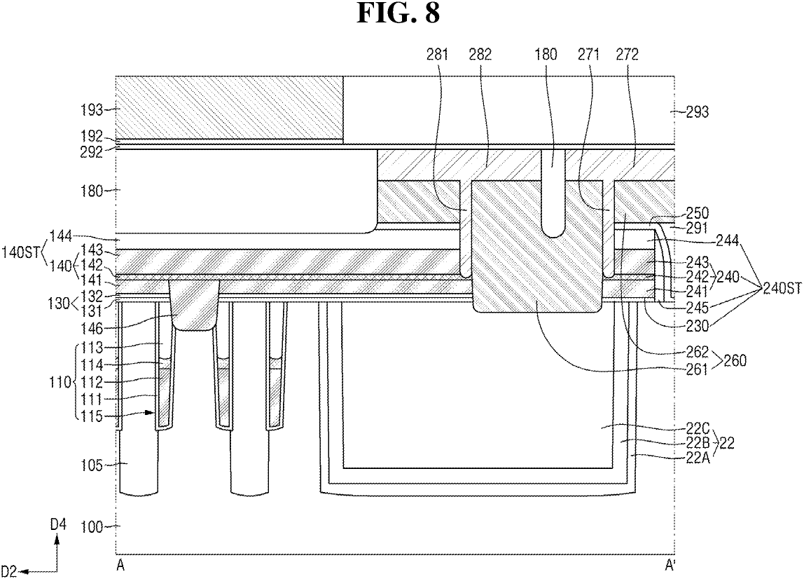

Referring to FIG. 8, in the semiconductor memory device according to some example embodiments, the first portion 261 of the isolation insulating layer 260 may be in contact with the peripheral gate contact plug 271 and the bit line contact plug 281. For example, the first portion 261 of the isolation insulating layer 260 may be in contact with at least some of sidewalls of the peripheral gate contact plug 271 and the bit line contact plug 281.

For example, the first portion 261 may be in contact with at least a portion of a sidewall of the peripheral gate contact plug 271 and at least a portion of a sidewall of the bit line contact plug 281.

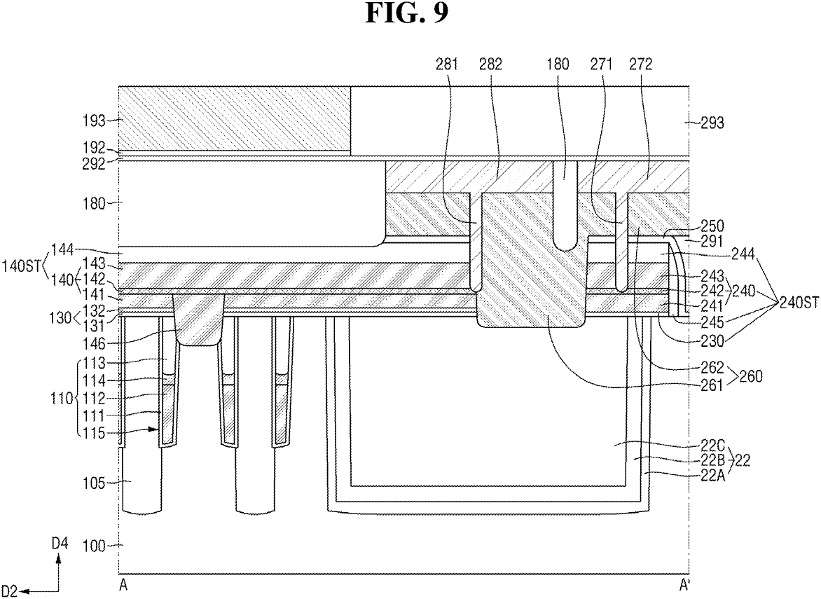

Referring to FIG. 9, in the semiconductor memory device according to some example embodiments, the first portion 261 of the isolation insulating layer 260 may be in contact with at least a portion of a sidewall and at least a portion of a bottom surface of any one of the peripheral gate contact plug 271 and the bit line contact plug 281.

For example, the first portion 261 may be in contact with at least a portion of a sidewall and at least a portion of a bottom surface of the bit line contact plug 281.

Alternatively, the first portion 261 of the isolation insulating layer 260 may be in contact with at least a portion of a sidewall of each of the peripheral gate contact plug 271 and the bit line contact plug 281 and at least a portion of a bottom surface of each of the peripheral gate contact plug 271 and the bit line contact plug 281. Alternatively, the first portion 261 of the isolation insulating layer 260 may be in contact with at least a portion of a sidewall of any one of the peripheral gate contact plug 271 and the bit line contact plug 281, and may be in contact with at least a portion of a sidewall and at least a portion of the bottom surface of the other.

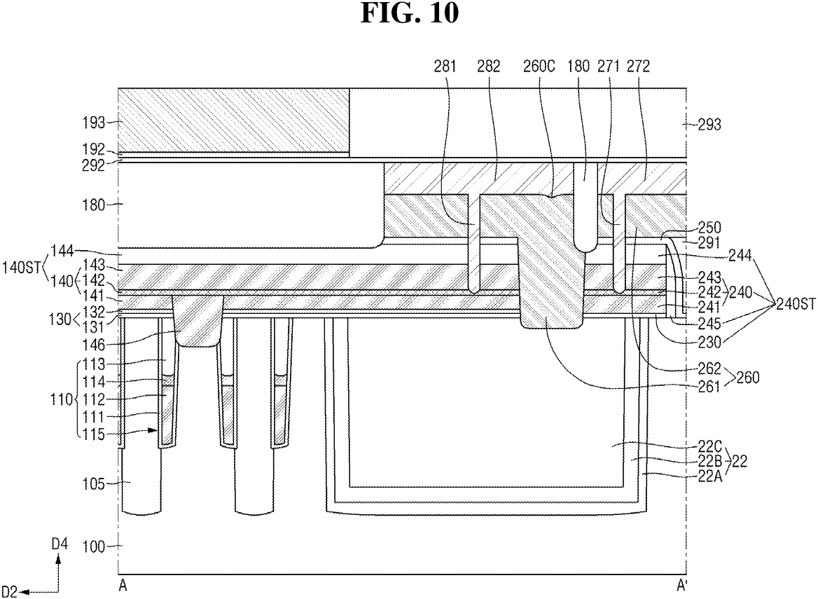

Referring to FIG. 10, in the semiconductor memory device according to some example embodiments, a top surface of the second portion 262 of the isolation insulating layer 260 may include a concave portion 260C toward the substrate 100. For example, the concave portion 260C may be formed on the first portion 261, but is not limited thereto. The concave portion 260C may not overlap the first portion 261 in the fourth direction D4.

The peripheral connection wiring 272 or the cell connection wiring 282 may fill the concave portion 260C.

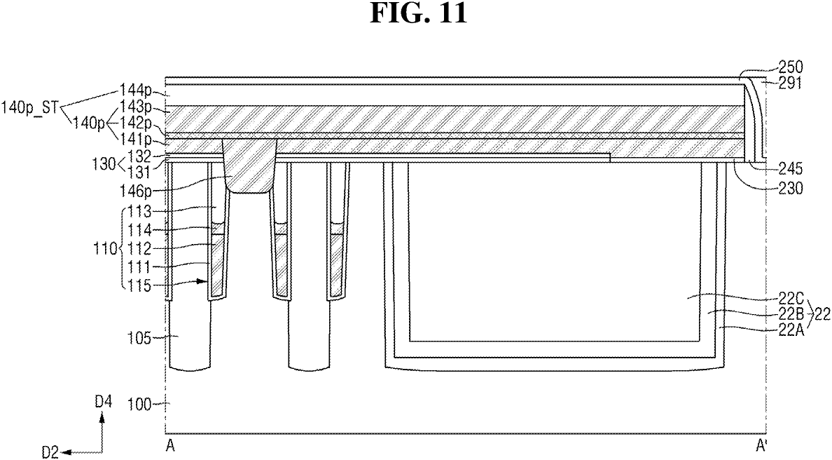

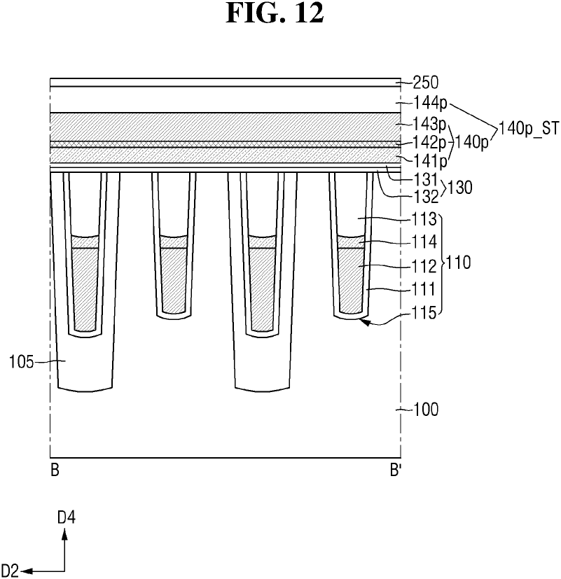

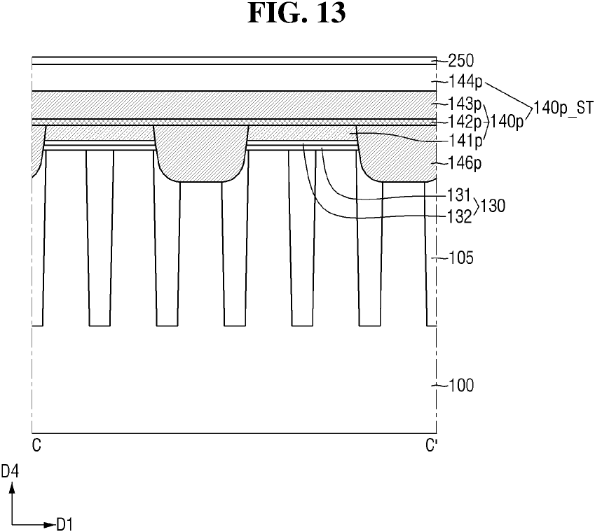

FIGS. 11 to 18 are intermediate operation views for describing the method for manufacturing a semiconductor memory device according to some example embodiments. The contents overlapping those described with reference to FIGS. 1 to 10 will be briefly described or omitted. For reference, FIGS. 11 and 14 to 18 are cross-sectional views taken along line A-A′ of FIG. 3, FIG. 12 is a cross-sectional view taken along line B-B′ of FIG. 3, and FIG. 13 is a cross-sectional view taken along line C-C′ of FIG. 3.

Referring to FIGS. 11 to 13, a substrate 100 including a cell region 20, a peripheral region 24, and a cell region isolation layer 22 is provided.

A cell gate structure 110 may be formed in the substrate 100 of the cell region 20. The cell gate structure 110 may extend to be long in a first direction D1. The cell gate structure 110 may include a cell gate trench 115, a cell gate insulating layer 111, a cell gate electrode 112, a cell gate capping pattern 113, and a cell gate capping conductive layer 114.

Subsequently, a cell insulating layer 130 may be formed on the cell region 20. The cell insulating layer 130 may expose the substrate 100 of the peripheral region 24.

Subsequently, a cell conductive layer structure 140p_ST may be formed on the substrate 100 of the cell region 20. The cell conductive layer structure 140p_ST may be formed on the cell insulating layer 130. In addition, a pre-bit line contact 146p may be formed between the cell conductive layer structure 140p_ST and the substrate 100. The pre-bit line contact 146p may connect the cell conductive layer structure 140p_ST and the substrate 100 to each other.

The cell conductive layer structure 140p_ST may include a pre-cell conductive line 140p and a pre-cell capping layer 144p that are sequentially stacked on the cell insulating layer 130. The pre-cell conductive line 140p may include a first pre-cell conductive layer 141p, a second pre-cell conductive layer 142p, and a third pre-cell conductive layer 143p that are sequentially stacked on the cell insulating layer 130. The pre-cell capping layer 144p may be formed on the third pre-cell conductive layer 143p.

A peripheral gate insulating layer 230 may be formed on the substrate 100 of the peripheral region 24. The closest peripheral gate insulating layer 230 may extend on the cell region isolation layer 22. For example, the peripheral gate insulating layer 230 closest to the cell conductive layer structure 140p_ST may be in contact with the cell insulating layer 130. The cell conductive layer structure 140p_ST may extend on the peripheral gate insulating layer 230 and the substrate 100 of the peripheral region 24.

Subsequently, the cell conductive layer structure 140p_ST formed on the substrate 100 of the peripheral region 24 may be etched to form a peripheral gate conductive layer and a peripheral capping layer. A peripheral spacer surrounding the peripheral gate conductive layer and the peripheral capping layer may be formed. Accordingly, a peripheral gate structure may be formed on the peripheral region 24. In this case, the cell conductive layer structure 140p_ST extending on the cell region isolation layer 22 may not be etched. Accordingly, the cell conductive layer structure 140p_ST extends on the peripheral gate insulating layer 230 closest to the cell conductive layer structure 140p_ST, and a peripheral spacer 245 is formed on a sidewall of the cell conductive layer structure 140p_ST.

Subsequently, a lower etching stop layer 250 may be formed on the substrate 100, the cell conductive layer structure 140p_ST, and the peripheral gate structure on the peripheral region 24. The lower etching stop layer 250 may extend along profiles of the top surface of the cell conductive layer structure 140p_ST, the peripheral spacer 245 formed on the sidewall of the cell conductive layer structure 140p_ST, and the peripheral gate structure on the peripheral region 24.

Subsequently, a first peripheral interlayer insulating layer 291 may be formed on the lower etching stop layer 250. After forming the first peripheral interlayer insulating layer 291 covering the lower etching stop layer 250, the first peripheral interlayer insulating layer 291 on the top surface of the cell conductive layer structure 140p_ST and the top surface of the peripheral gate structure may be removed by using a chemical mechanical polishing (CMP) process. Accordingly, the lower etching stop layer 250 on the top surface of the cell conductive layer structure 140p_ST and the top surface of the peripheral gate structure are exposed.

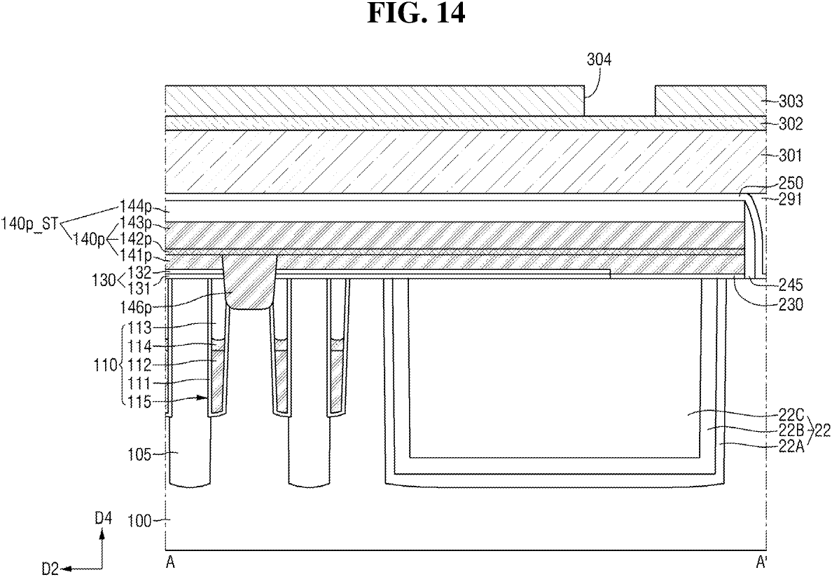

Referring to FIG. 14, a plurality of hard mask patterns 301, 302, and 303 may be formed on the lower etching stop layer 250 and the first peripheral interlayer insulating layer 291. The plurality of hard mask patterns 301, 302, and 303 may include, for example, first to third hard mask patterns 301, 302, and 303 sequentially stacked. The third hard mask pattern 303 may include an opening 304. The opening 304 may overlap a portion in which the cell insulating layer 130 and the peripheral gate insulating layer 230 are in contact with each other in the fourth direction D4.

Subsequently, a patterning process may be performed using the plurality of hard mask patterns 301, 302, and 303.

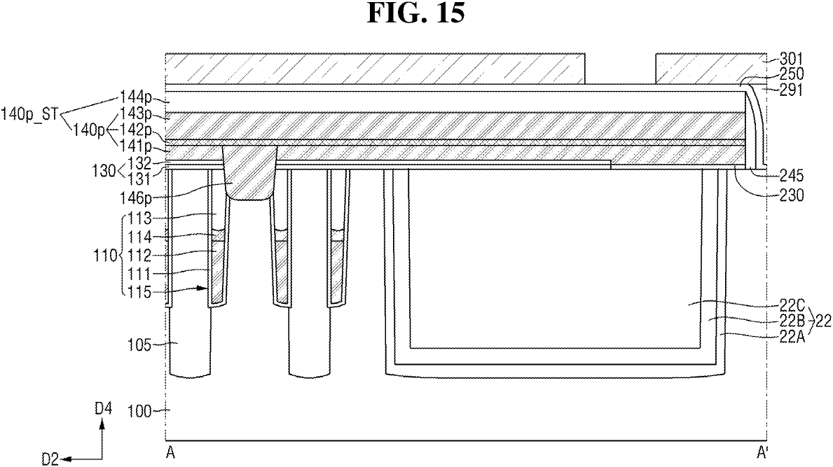

Referring to FIG. 15, a first hard mask pattern 301 having an opening corresponding to the opening 304 of FIG. 14 may be generated. The lower etching stop layer 250, the cell conductive layer structure 140p_ST, the cell insulating layer 130, and the peripheral gate insulating layer 230 may be etched using the first hard mask pattern 301.

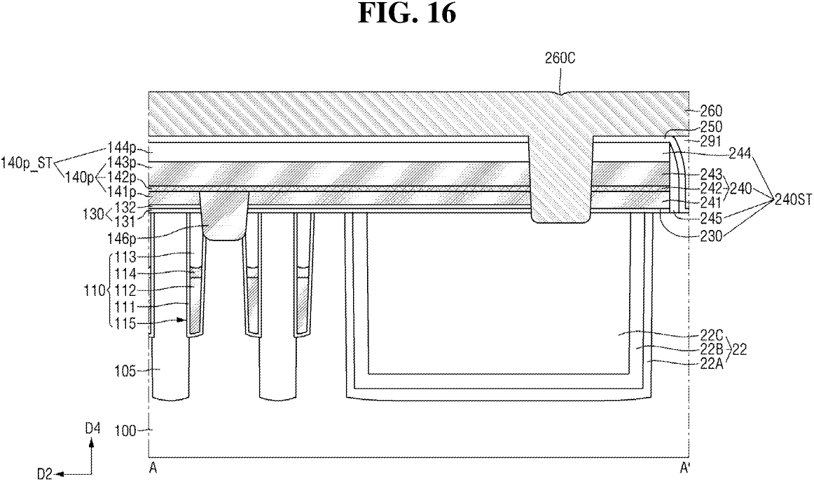

Referring to FIG. 16, the cell conductive layer structure 140p_ST may be isolated by an etching process using the first hard mask pattern 301 of FIG. 15. Accordingly, a peripheral gate structure 240ST closest to the cell conductive layer structure 140p_ST may be formed. The peripheral gate structure 240ST may include a peripheral gate insulating layer 230, a peripheral gate conductive layer 240, and a peripheral spacer 245.

Subsequently, an isolation insulating layer 260 covering the cell conductive layer structure 140p_ST and the peripheral gate structure 240ST may be formed. The isolation insulating layer 260 may be formed by the etching process to fill a trench isolating the cell conductive layer structure 140p_ST and the peripheral gate structure 240ST from each other. Accordingly, the isolation insulating layer 260 isolating the cell conductive layer structure 140p_ST and the peripheral gate structure 240ST closest to the cell conductive layer structure 140p_ST from each other may be formed.

In this case, according to some embodiments, a concave portion 260C may be formed on a top surface of the isolation insulating layer 260. The concave portion 260C may be formed according to a width of the isolation insulating layer 260 isolating the cell conductive layer structure 140p_ST and the peripheral gate structure 240ST closest to the cell conductive layer structure 140p_ST from each other. In this case, the isolation insulating layer 260 as illustrated in FIG. 10 may be formed.

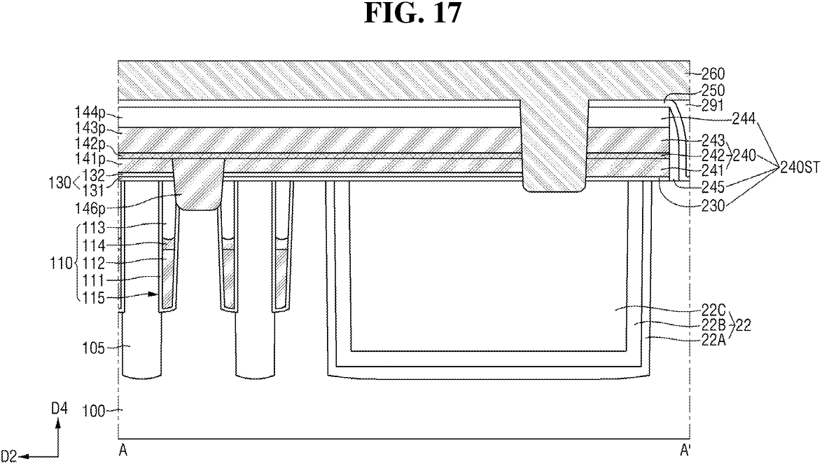

Referring to FIGS. 16 and 17, according to some example embodiments, the concave portion 260C may not be formed on the top surface of the isolation insulating layer 260. Alternatively, according to some example embodiments, a portion of the isolation insulating layer 260 may be etched to remove the concave portion 260C.

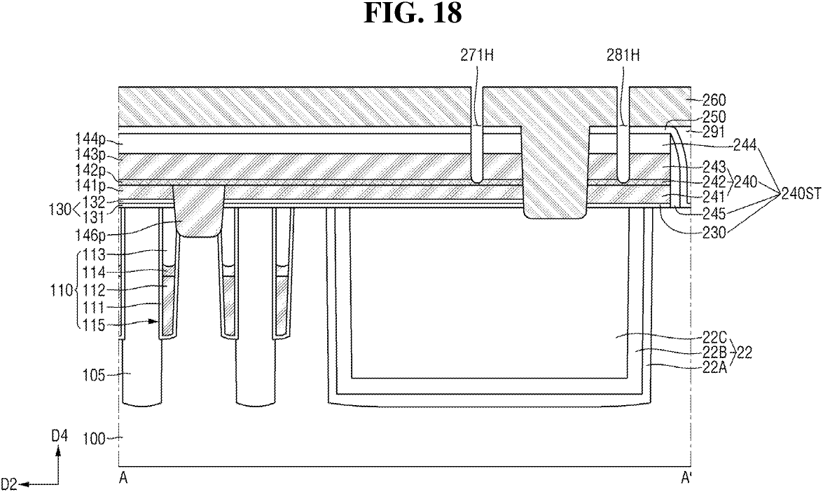

Referring to FIG. 18, a first through hole 271H and a second through hole 281H penetrating through the isolation insulating layer 260 may be formed. The first through hole 271H may be formed at an end side of the cell conductive layer structure 140p_ST, and the second through hole 281H may be formed at an end side of the peripheral gate conductive layer 240 closest to the cell conductive layer structure 140p_ST. The first through hole 271H may penetrate through the isolation insulating layer 260 and the cell conductive layer structure 140p_ST, and the second through hole 281H may penetrate through the isolation insulating layer 260 and the peripheral gate conductive layer 240.

A bottom surface of the first through hole 271H may be disposed in the first to third pre-cell conductive layers 141p, 142p, and 143p, and a bottom surface of the second through hole 281H may be disposed in the first to third peripheral conductive layers 241, 242, and 243.

Then, referring to FIGS. 4 to 6, a bit line structure 140ST extending to be long in the second direction D2 may be formed by patterning the cell conductive layer structure 140p_ST and the lower etching stop layer 250. While the bit line structure 140ST is formed, a bit line contact 146 may be formed.

After the cell line spacer 150 is formed, a fence pattern 170, a storage contact 120, and a storage pad 160 may be formed.

A peripheral gate contact plug 271 filling the first through hole 271H and a peripheral connection wiring 272 connected to the peripheral gate contact plug 271 on the isolation insulating layer 260 may be formed. A bit line contact plug 281 filling the second through hole 281H and a cell connection wiring 282 connected to the bit line contact plug 281 on the isolation insulating layer 260 may be formed.

Subsequently, an upper etching stop layer 292 may be formed. In addition, an information storage portion 190 may be formed.

That is, in the method of manufacturing a semiconductor memory device according to some example embodiments, the manufacturing processes described with reference to FIGS. 14 to 18 may be performed before forming the bit line structure 140ST.

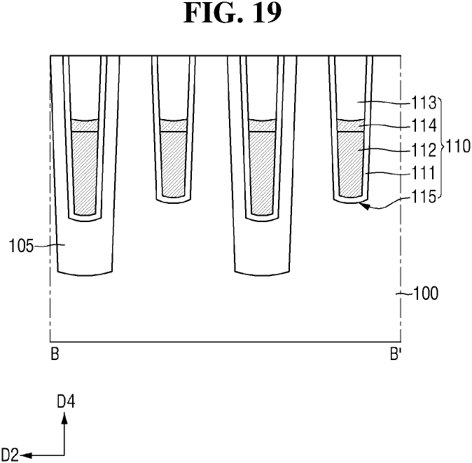

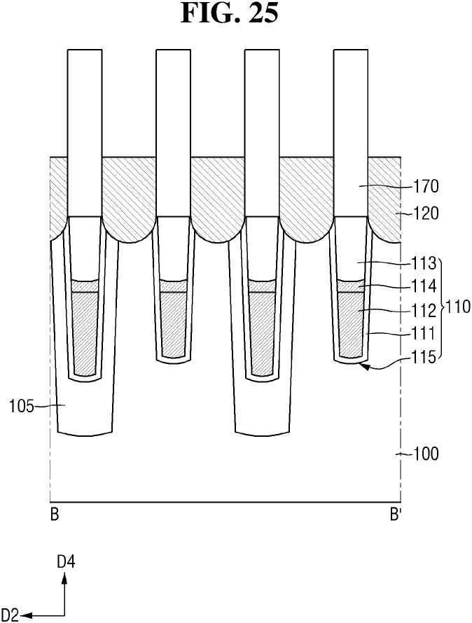

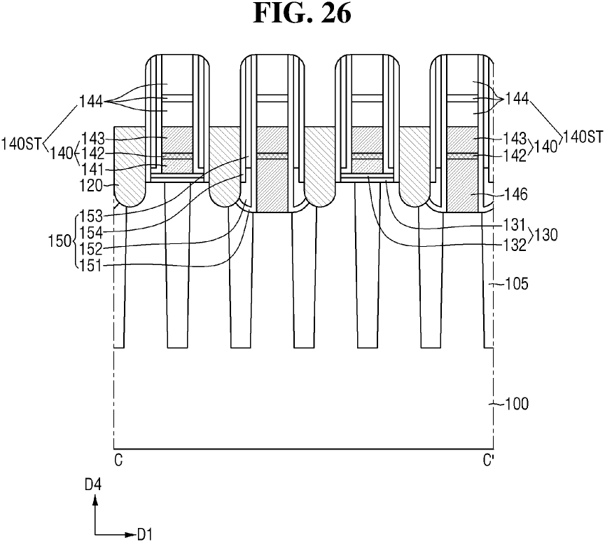

FIGS. 19 to 26 are intermediate operation views for describing the method for manufacturing a semiconductor memory device according to some example embodiments. The contents overlapping those described with reference to FIGS. 1 to 18 will be briefly described or omitted. For reference, FIGS. 19, 21, 23, and 25 are cross-sectional views taken along line B-B′ of FIG. 3, and FIGS. 20, 22, 24, and 26 are cross-sectional views taken along line C-C′ of FIG. 3.

In the method of manufacturing a semiconductor memory device according to some example embodiments, the manufacturing processes described with reference to FIGS. 14 to 18 may be performed before forming the information storage portion 190.

In the method of manufacturing a semiconductor memory device according to some example embodiments, the manufacturing processes described with reference to FIGS. 14 to 18 may be performed before forming the bit line structure 140ST and forming the cell line spacer 150.

For example, referring to FIGS. 11, 19, and 20, the bit line structure 140ST extending to be long in the second direction D2 may be formed by patterning the cell conductive layer structure 140p_ST and the lower etching stop layer 250. While the bit line structure 140ST is formed, a bit line contact 146 may be formed. Subsequently, the manufacturing processes described with reference to FIGS. 14 to 18 may be performed. Subsequently, the cell line spacer 150, the fence pattern 170, the storage contact 120, the storage pad 160, the peripheral gate contact plug 271, the peripheral connection wiring 272, the bit line contact plug 281, the cell connection wiring 282, the upper etching stop layer 292, and the information storage portion 190 may be formed.

In the method of manufacturing a semiconductor memory device according to some example embodiments, the manufacturing processes described with reference to FIGS. 14 to 18 may be performed before forming the cell line spacer 150 and forming the fence pattern 170.

For example, referring to FIGS. 11, 21, and 22, after the bit line structure 140ST and the bit line contact 146 are formed as illustrated in FIGS. 19 and 20, the cell line spacer 150 may be formed. Subsequently, the manufacturing processes described with reference to FIGS. 14 to 18 may be performed. Subsequently, the fence pattern 170, the storage contact 120, the storage pad 160, the peripheral gate contact plug 271, the peripheral connection wiring 272, the bit line contact plug 281, the cell connection wiring 282, the upper etching stop layer 292, and the information storage portion 190 may be formed.

In the method of manufacturing a semiconductor memory device according to some example embodiments, the manufacturing processes described with reference to FIGS. 14 to 18 may be performed before forming the fence pattern 170 and forming the storage contact 120.

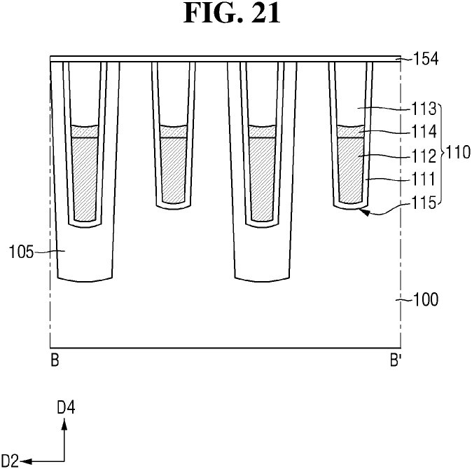

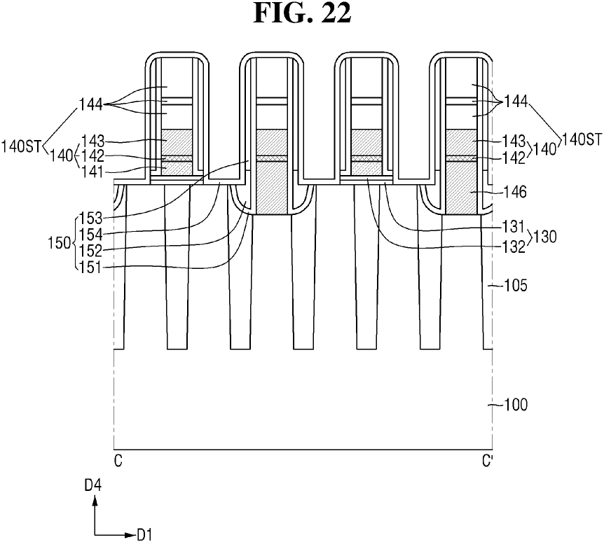

For example, referring to FIGS. 11, 23, and 24, after the bit line structure 140ST, the bit line contact 146, and the cell line spacer 150 are formed as illustrated in FIGS. 21 and 22, the fence pattern 170 may be formed. Subsequently, the manufacturing processes described with reference to FIGS. 14 to 18 may be performed. Subsequently, the storage contact 120, the storage pad 160, the peripheral gate contact plug 271, the peripheral connection wiring 272, the bit line contact plug 281, the cell connection wiring 282, the upper etching stop layer 292, and the information storage portion 190 may be formed.

In the method of manufacturing a semiconductor memory device according to some example embodiments, the manufacturing processes described with reference to FIGS. 14 to 18 may be performed before forming the storage contact 120 and forming the storage pad 160.

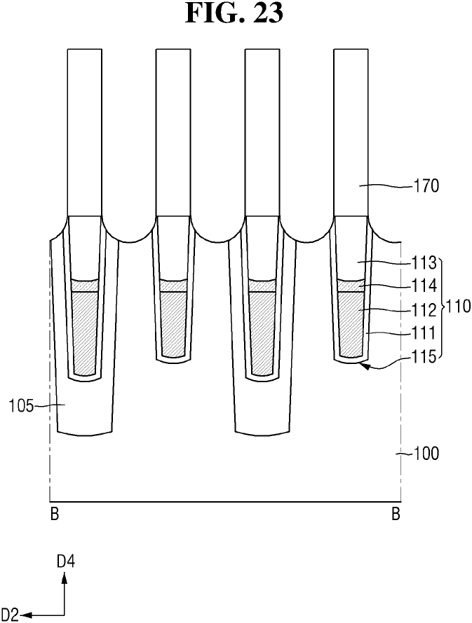

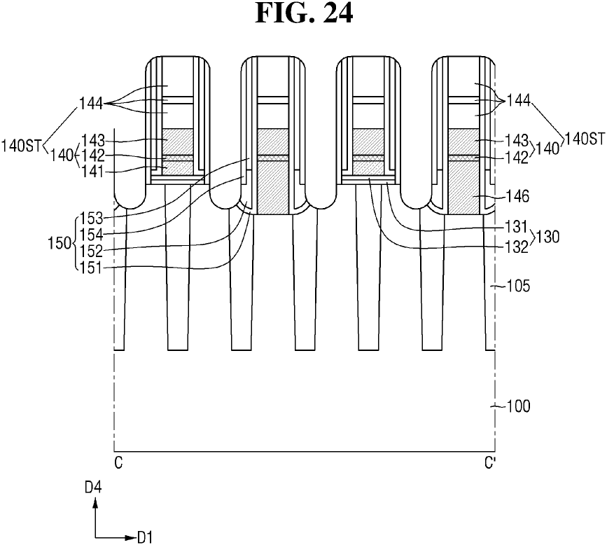

For example, referring to FIGS. 11, 25, and 26, after the bit line structure 140ST, the bit line contact 146, the cell line spacer 150, and the fence pattern 170 are formed as illustrated in FIGS. 23 and 24, the storage contact 120 may be formed. Subsequently, the manufacturing processes described with reference to FIGS. 14 to 18 may be performed. Subsequently, the storage pad 160, the peripheral gate contact plug 271, the peripheral connection wiring 272, the bit line contact plug 281, the cell connection wiring 282, the upper etching stop layer 292, and the information storage portion 190 may be formed.

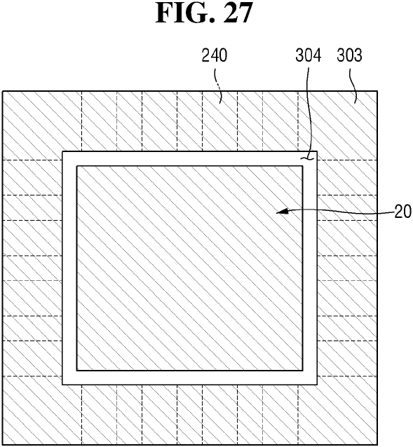

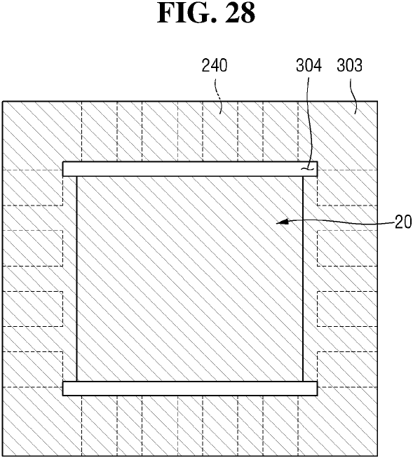

FIGS. 27 and 28 are views for describing a hard mask pattern of FIG. 14.

Referring to FIGS. 14, 15, and 17, in the method of manufacturing a semiconductor memory device according to some example embodiments, the third hard mask pattern 303 may include an opening 304. The opening 304 may have a ring shape. The opening 304 may be formed along a periphery of the cell region 20. The opening 304 may be formed between the cell region 20 and the peripheral gate conductive layer 240 to be formed later. The isolation insulating layer 260 may be formed in a portion etched through the opening 304. That is, the isolation insulating layer 260 may be formed along the periphery of the cell region 20.

Referring to FIGS. 14, 15, and 28, in the method of manufacturing a semiconductor memory device according to some example embodiments, the opening 304 of the third hard mask pattern 303 may have a slit shape. The opening 304 may be formed on opposite sidewalls of the cell region 20. The opening 304 may be formed between both sidewalls of the cell region 20 opposite to each other in the second direction D2, which is a direction in which the bit line structure 140ST extends to be long later and the peripheral gate conductive layer 240 to be formed later. Both sidewalls of the cell region 20 opposite to each other in the first direction D1 and the peripheral gate conductive layer 240 may be formed simultaneously with the formation of the peripheral gate conductive layer on the substrate 100 of the peripheral region 24.

While some example embodiments of the present disclosure have been described above with reference to the accompanying drawings, inventive concepts may be implemented in various different forms. Those skilled in the art to which the present disclosure pertains may understand that embodiments of inventive concepts may be implemented in other specific forms without departing from the spirit and scope of inventive concepts. Therefore, it should be understood that the example embodiments described above are illustrative in all aspects and not restrictive.

What is claimed is:

1. A semiconductor memory device comprising:
a substrate including a cell region and a peripheral region along a periphery of the cell region;
a cell region isolation layer in the substrate, the cell region isolation layer along the periphery of the cell region and defining the cell region of the substrate;
a cell conductive line on the cell region, the cell conductive line including a sidewall on the cell region isolation layer;
a peripheral gate conductive layer on the peripheral region, the peripheral gate conductive layer including a sidewall on the cell region isolation layer; and
an isolation insulating layer in contact with the sidewall of the cell conductive line and the sidewall of the peripheral gate conductive layer on the cell region isolation layer.

2. The semiconductor memory device of claim 1, wherein the isolation insulating layer is a single layer.

3. The semiconductor memory device of claim 1, wherein the sidewall of the cell conductive line and the sidewall of the peripheral gate conductive layer face each other.

4. The semiconductor memory device of claim 1, wherein
the cell conductive line includes a first sidewall facing a direction in which the cell conductive line extends, and
the isolation insulating layer is in contact with the first sidewall.

5. The semiconductor memory device of claim 4, further comprising:
a cell line spacer, wherein
the cell conductive line further includes a second sidewall facing a direction intersecting the direction in which the cell conductive line extends, and
the cell line spacer is on the second sidewall of the cell conductive line and not on the first sidewall of the cell conductive line.

6. The semiconductor memory device of claim 1, further comprising:
a peripheral spacer, wherein
the peripheral gate conductive layer includes a first sidewall in contact with the isolation insulating layer and a second sidewall opposite the first sidewall,
the peripheral spacer is on the second sidewall of the peripheral gate conductive layer, and
the peripheral spacer is not on the first sidewall of the peripheral gate conductive layer.

7. The semiconductor memory device of claim 6, wherein
the peripheral gate conductive layer further includes a third sidewall connecting the first sidewall and the second sidewall to each other, and
the peripheral spacer is on the third sidewall.

8. The semiconductor memory device of claim 1, further comprising:
a bit line contact plug; and
a peripheral gate contact plug, wherein
the isolation insulating layer includes a first portion and a second portion,
the first portion of the isolation insulating layer is in contact with the sidewall of the cell conductive line and the sidewall of the peripheral gate conductive layer,
the second portion of the isolation insulating layer extends along at least a portion of a top surface of the cell conductive line and at least a portion of a top surface of the peripheral gate conductive layer,
the bit line contact plug penetrates through the second portion of the isolation insulating layer and is electrically connected to the cell conductive line, and
the peripheral gate contact plug penetrates through the second portion of the isolation insulating layer and is electrically connected to the peripheral gate conductive layer.

9. The semiconductor memory device of claim 8, wherein the first portion of the isolation insulating layer is spaced apart from the bit line contact plug and the peripheral gate contact plug.

10. The semiconductor memory device of claim 8, wherein the first portion of the isolation insulating layer is in contact with at least one of the bit line contact plug and the peripheral gate contact plug.

11. The semiconductor memory device of claim 10, wherein a portion of at least one of a bottom surface of the bit line contact plug and a bottom surface of the peripheral gate contact plug is in contact with the first portion of the isolation insulating layer.

12. The semiconductor memory device of claim 1, wherein the isolation insulating layer is along the periphery of the cell region.

13. The semiconductor memory device of claim 1, wherein a bottom surface of the isolation insulating layer is below a top surface of the cell region isolation layer.

14. A semiconductor memory device comprising:
a substrate including a cell region and a peripheral region along a periphery of the cell region;
a cell conductive line on the cell region;
a peripheral gate conductive layer on the peripheral region, the peripheral gate conductive layer including a first sidewall opposite the cell conductive line in a first direction and a second sidewall opposite the first sidewall in the first direction;
a peripheral spacer that is not on the first sidewall and is disposed on the second sidewall; and
an isolation insulating layer between the cell conductive line and the first sidewall.

15. The semiconductor memory device of claim 14, wherein the isolation insulating layer is a single layer.

16. The semiconductor memory device of claim 14, wherein the cell conductive line extends lengthwise in the first direction.

17. The semiconductor memory device of claim 14, further comprising:
a bit line contact plug; and
a peripheral gate contact plug, wherein
the isolation insulating layer includes a first portion and a second portion,
the first portion of the isolation insulating layer is between the cell conductive line and the first sidewall, the second portion of the isolation insulating layer extends along at least a portion of a top surface of the cell conductive line and at least a portion of a top surface of the peripheral gate conductive layer,
the bit line contact plug penetrates through the second portion of the isolation insulating layer and is electrically connected to the cell conductive line, and
the peripheral gate contact plug penetrates through the second portion of the isolation insulating layer and is electrically connected to the peripheral gate conductive layer.

18. The semiconductor memory device of claim 17, wherein a top surface of the second portion of the isolation insulating layer includes a concave portion recessed toward the substrate.

19. A semiconductor memory device comprising:
a substrate including a cell region and a peripheral region defined around the cell region;
a cell region isolation layer defining the cell region in the substrate;
a bit line structure on the substrate in the cell region, the bit line structure including a cell conductive line extending in a first direction and a cell line capping layer on the cell conductive line;
a cell gate electrode in the substrate in the cell region, the cell gate electrode extending in a second direction to intersect the cell conductive line, the second direction intersecting the first direction;
a peripheral gate structure on the substrate in the peripheral region, the peripheral gate structure including a peripheral gate conductive layer and a peripheral capping layer on the peripheral gate conductive layer;
an isolation insulating layer isolating the bit line structure and the peripheral gate structure from each other, the isolation insulating layer on the cell region isolation layer between the bit line structure and the peripheral gate structure, and the isolation insulating layer being a single layer;
a bit line spacer on sidewalls of the bit line structure facing the second direction, and the bit line spacer not on sidewalls of the bit line structure facing the first direction; and
a peripheral spacer on a sidewall of the peripheral gate structure facing the second direction and a sidewall of the peripheral gate structure facing the first direction in which the isolation insulating layer is not disposed, and the peripheral spacer not on a sidewall of the peripheral gate structure facing the first direction in which the isolation insulating layer is disposed.

20. The semiconductor memory device of claim 19, further comprising:
a peripheral interlayer insulating layer around the peripheral gate structure on the substrate in the peripheral region, wherein
the peripheral interlayer insulating layer is not on a sidewall of the peripheral gate structure in which the isolation insulating layer is disposed and the peripheral spacer is not disposed.
